(19) United States
(12) Patent Application Publication
(10) Pub. No.: US 2013/0082292 A1
(43) Pub. Date: Apr. 4, 2013

(54) Light Emitting Diode Packaging Structure and Method of Fabricating the Same

(71) Applicants: Shih-Long Wei, Hsinchu County (TW); Shen-Li Hsiao, Hsinchu County (TW); Chien-Hung Ho, Hsinchu County (TW)

(72) Inventors: Shih-Long Wei, Hsinchu County (TW); Shen-Li Hsiao, Hsinchu County (TW); Chien-Hung Ho, Hsinchu County (TW)

(73) Assignee: VIKING TECH CORPORATION, Hsinchu Country (TW)

(21) Appl. No.: 13/314,432

(22) Filed: Dec. 8, 2011

(30) Foreign Application Priority Data
Sep. 29, 2011 (TW) 100135191

(51) Int. Cl. H01L 33/60; B32B 38/04; B32B 37/12; B32B 37/14; B32B 37/06; B32B 37/10

(52) U.S. Cl. 257/98; 156/285; 156/257; 156/272.8; 156/242; 257/E33.06

(57) ABSTRACT

A method of fabricating alight emitting diode packaging structure provides a metallized ceramic heat dissipation substrate and a reflector layer, and the metallized ceramic heat dissipation substrate is bonded with the reflector layer through an adhesive. The reflector layer has an opening for a surface of the metallized ceramic heat dissipation substrate to be exposed therefrom. The reflector layer may be formed with ceramic or polymer plastic material, to enhance the refractory property and the reliability of the package structure. In addition, the packaging structure of the present invention may make use of existing packaging machine for subsequent electronic component packaging, without increasing the fabrication cost.

### BACKGROUND OF THE INVENTION

1. Field of the Invention

The present invention relates generally to light emitting diode packaging structures and methods of fabricating the same, and, more particularly, to a light emitting diode packaging structure having improved reliability and a method of fabricating the same.

2. Description of Related Art

With the rapid development of electronic industry, electronic products are trending toward compact size, high performance, plenty of functionalities, high operation speed, etc. Among the electronic products for illumination, alight emitting diode (LED) is widely used due to its compact size and low power consumption.

A conventional LED, after mounted on a substrate, is encapsulated with a resin material, such as epoxy and silicone. For example, after the LED is mounted on the substrate, an encapsulating mold covers the LED and the encapsulant fills into the encapsulating mold, Although no additional device, such as a darn or a cavity, is needed to facilitate the of the encapsulant into the encapsulating mold, the machine used to package the LED module is very expensive and the encapsulant is still likely to be leaked from the encapsulant mold. In order to reduce the packaging costs, an additional device is provided to facilitate the filling of the encapsulant. Referring to FIG. 1, a cross-sectional view illustrating an LED package is shown. A reflector 110 is formed on a metal lead frame 100 by an injection molding method. A through opening 111 is formed in the reflector 110, and an LED 300 is disposed in the opening 111. An encapsulant 400 is filled into the opening 111 and seals the LED 300.

Although the above LED package is fabricating by using the expensive machine, there still exist various problems. The metal lead frame 100 and the reflector 110 are made of different materials, and a poor adhesion exists therebetween. The metal lead frame 100 is embedded in the reflector 110 by the injection molding method, so as to avoid the reflector 110 from being separated from the metal lead frame 100. However, the reflector 110 is made of plastic such as PA9T material, which is thermally stable but has a thermal conductivity as low as 0.2 W/m·K. The reflector 110 thus has poor heat dissipating capability, and the heat generated by the LED and currents supplied to the LED can only be transmitted through nowhere but the small-sized metal lead frame 100. Therefore, the overall thermal conductivity of the LED module is very low and the heat is easily accumulated in the LED module. In the long run, the reflector 110 will be embrittled or cracked under high temperature, and the lifetime or performance of the LED module will be reduced.

Therefore, how to provide an LED packaging structure having improved reliability, without increasing the packaging cost, is becoming one of the most popular issues in the art.

### SUMMARY OF THE INVENTION

In view of the above drawbacks of the prior art, the object of the present invention is to provide a method of integrating a heat dissipating substrate with a reflector layer by using an adhesive.

Another object of the present invention is to provide a light emitting diode packaging structure having improved reliability.

To achieve the objects above and other objects, the present invention provides a light emitting diode package structure, including: a metallized ceramic heat dissipation substrate; a reflector layer formed at one side of the metallized ceramic substrate and having an opening for a surface of the metallized ceramic substrate to be exposed therefrom; and an adhesive formed between the metallized ceramic substrate and the reflector layer for bonding the metallized ceramic substrate to the reflector layer.

In an embodiment of the present invention, the reflector layer is made of aluminum nitride, aluminum oxide or engineering plastics, such as PA9T and Teflon.

In an embodiment of the present invention, the aperture of the opening of the reflector layer is tapered toward the surface of the metallized ceramic substrate.

In an embodiment of the present invention, the packaging structure of the present invention further includes a circuit layer formed on the surface of the metallized ceramic substrate, and the adhesive covers the substrate and the circuit layer.

The present invention further provides a method of fabricating a light emitting diode package structure, including: providing a metallized ceramic heat dissipation substrate and a reflector layer; attaching an adhesive to one side of the reflector layer; forming an opening in the reflector layer attached to the adhesive; and aligning the metallized ceramic heat dissipation substrate with the reflector layer, so as to couple the metallized ceramic heat dissipation substrate to the reflector layer via the adhesive by a vacuum hot pressing process.

The present invention further provides a method of fabricating a light emitting diode package structure, including: providing a metallized ceramic heat dissipation substrate, a reflector layer having a first opening, and an adhesive having a second opening; aligning the first opening of the reflector layer with the second opening of the adhesive and stacking the metallized ceramic heat dissipation substrate on the adhesive which is adhered to the reflector layer; and coupling the metallized ceramic heat dissipation substrate to the reflector layer via the adhesive by a vacuum hot pressing process.

Compared to the prior art, the present invention provides a light emitting diode packaging structure and a method of fabricating the same, in which the reflector layer is made of the materials of ceramic or polymer engineering plastics, so as to avoid the reflector layer from being embrittled or cracked in the long ran when operating in high temperature. In addition, the present invention combines the metallized ceramic heat dissipation substrate and the reflector layer with the adhesive. In the packaging structure thus fabricated, the light-emitting diode may be packaged by using the existing packaging machines, and thus significantly reduce not only the packaging costs but also needless consumption of new machine equipment.

### BRIEF DESCRIPTION OF DRAWINGS

FIG. 1 is a cross-sectional view illustrating a light emitting diode package according to the prior art;

FIG. 2 is a cross-sectional view illustrating a light emitting diode packaging structure according to the present invention;

FIG. 3 is a cross-sectional view illustrating a light emitting diode packaging structure according to another embodiment of the present invention;

FIGS. 4A and 4B are cross-sectional views illustrating a light emitting diode packaging structure according to another embodiment of the present invention;

FIGS. 5A to 5E are cross-sectional views illustrating a method of fabricating a light emitting diode packaging structure according to the present invention; and

FIGS. 6A to 6D are cross-sectional views illustrating a method of fabricating a light emitting diode packaging structure according to another embodiment of the present invention.

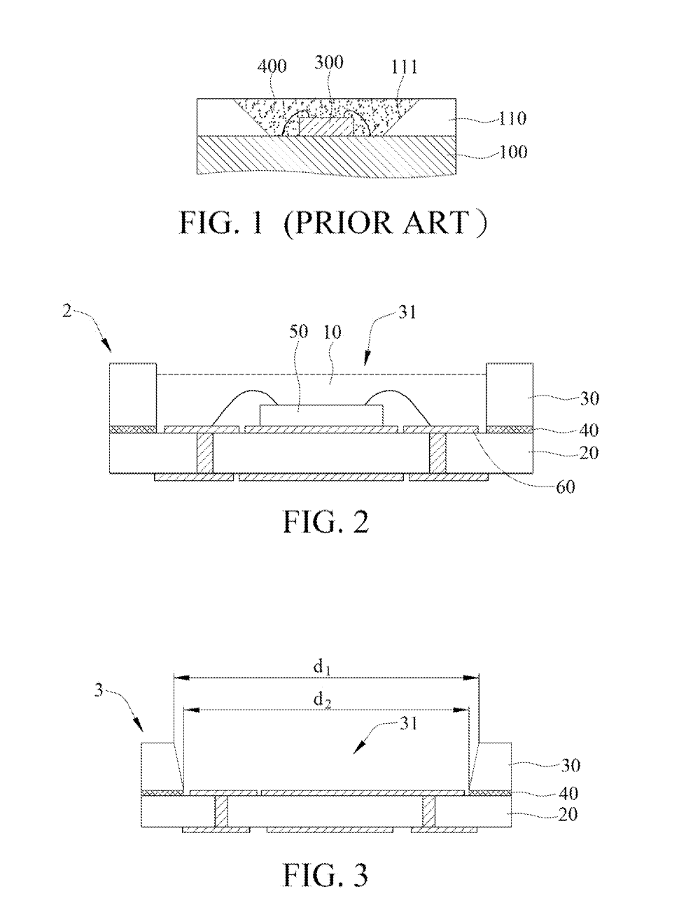

### DETAILED DESCRIPTION OF PREFERRED EMBODIMENTS

It is to be understood that both the foregoing general descriptions and the detailed embodiments are exemplary and are, together with the accompanying drawings, intended to provide further explanation of technical features and advantages of the invention.

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be devised without departing from the spirit of the present invention.

FIG. 2 is a cross-sectional view illustrating a light emitting diode packaging structure according to the present invention. The packaging structure 2 includes a metallized ceramic heat dissipation substrate 20, a reflector layer 30, and an adhesive 40. First, the metallized ceramic heat dissipation substrate 20 is provided, and the reflector layer 30 is disposed at one side of the metallized ceramic heat dissipation substrate 20. The reflector layer 30 has an opening 31 for a surface of the metallized ceramic heat dissipation substrate 20 to be exposed therefrom. The adhesive 40 such as the acrylic adhesive is formed between the metallized ceramic heat dissipation substrate 20 and the reflector layer 30, and bonds the metallized ceramic heat dissipation substrate 20 to the reflector layer 30.

In the packaging structure 2, a light emitting device 50 may be disposed on a circuit layer 60 formed on the surface of the metallized ceramic heat dissipation substrate 20 and electrically connected to the circuit layer 60. An encapsulant 10 is formed in the opening 31 and covers the surface of the metallized ceramic heat dissipation substrate 20, the circuit layer 60, and the light emitting device 50 in the opening 31, thus completing the package process of the LED element. The encapsulant 10 is formed by glue filling, glue injecting or glue dispensing.

The metallized ceramic heat dissipation substrate 20 has well thermal and electric separation capability, capable of improving the reliability of the light emitting device 50. In order to prevent the reflector layer 30 from being cracked, the reflector layer 30 may be made of aluminum nitride (AlN), alumina (Al₂O₃) or PA9T polymer plastics, and the metallized ceramic heat dissipation substrate 20 may be made of MN or Al₂O₃.

The aforementioned light emitting diode packaging structure is applicable to the packaging of the current LED die and the heat dissipation substrate. Referring to FIG. 2, the LED die (i.e., the light emitting device 50) is wire bonded to the heat dissipation substrate, However, any other method, such as eutectic bonding and flip-chip bonding, may also be applicable to the packaging structure of the present invention.

Referring to FIG. 3, a cross-sectional view illustrating alight emitting diode packaging structure according to another embodiment of the present invention is provided. in this embodiment, the aperture of the opening 31 in the packaging structure 3 is tapered toward the surface of the metallized ceramic heat dissipation substrate 20. Specifically, the reflector layer 30 bonding to the surface of the metallized ceramic heat dissipation substrate 20 by using the adhesive 40 may has a structure with inclined planes. Referring to FIG. 3, the opening 31 formed in the reflector layer 30 has a first aperture of distance d1 which is far from the metallized ceramic heat dissipation substrate 20, and a second aperture of distance d2 which is close to the metallized ceramic heat dissipation substrate 20. In this embodiment, the distance d1 is greater than the distance d2, such that the reflector layer 30 has an internally inclined plane. Such a light emitting device provides a better reflection effect, and has a light emitting angle that may be designed on users' demands.

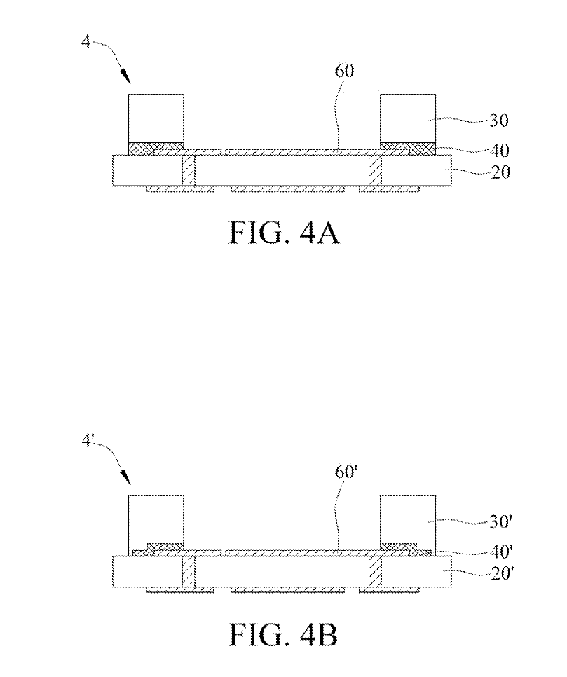

Referring to FIGS. 4A and 4B, cross-sectional views illustrating a light emitting diode packaging structure according to another embodiment of the present invention are provided. In this embodiment, the surface of the metallized ceramic heat dissipation substrate 20 of the packaging structure 4 further includes a circuit layer 60, and the adhesive 40 covers the metallized ceramic heat dissipation substrate 20 and the circuit layer 60. The circuit layer 60 is provided on the metallized ceramic heat dissipation substrate 20, and thus the height difference generates between the circuit layer 60 and the metallized ceramic heat dissipation substrate 20. With good step coverage and flexibility of the adhesive 40 or the reflector layer 30, the adhesive 40 can be covered well on the metallized ceramic heat dissipation substrate 20 and the circuit layer 60 to maintain the air tightness.

As shown in FIG. 4A, the adhesive 40 for joining the metallized ceramic heat dissipation substrate 20 and the reflector layer 30 may cover a portion of the surface of the metallized ceramic heat dissipation substrate 20 and may also cover the circuit layer 60. In another embodiment shown in FIG. 4B, the adhesive 40′ may cover the metallized ceramic heat dissipation substrate 20′ and the circuit layer 60′, in which the adhesive 40′ is uniform in thickness. It means that the reflector layer 30′ may be conformable to the profile of the circuit layer 60 and the metalized ceramic heat dissipation substrate 20.

From the foregoing, when the reflector layer is made of ceramic materials, such as aluminum nitride or alumina, the defects caused due to that the reflector layer is easily embrittled and cracked under high temperature in the long term may be avoided because of the same materials. In addition, owing to the superior heat dissipating capacity of the metallized ceramic heat dissipation substrate, the heat generated by the LED die will not be accumulated, and thus polymer plastics such as PAT or Teflon are also suitable for the reflector layer structure of the high power LED packaging. Furthermore, the present invention adopts the adhesive to integrate the reflector layer with the metallized ceramic heat dissipation substrate. Not only the reliability is improved, but also the subsequent electronic component packaging can be performed using the existing packaging machine without increasing the cost of new equipment.

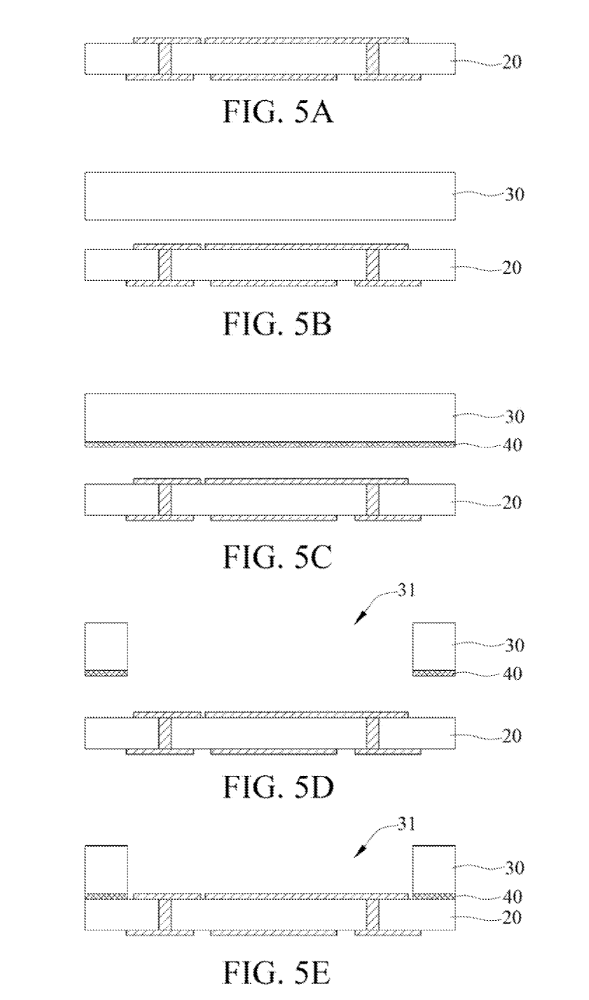

Referring to FIGS. 5A to 5E, cross-sectional views illustrating a method of fabricating a light emitting diode packaging structure according to the present invention are provided.

As shown in FIG. 5A, a metallized ceramic heat dissipation substrate 20 is provided, a circuit layer is disposed on the surface of the metallized ceramic heat dissipation substrate 20, and the metallized ceramic heat dissipation substrate 20 has a good thermal and electric separation capability.

As shown in FIG. 5B, a reflector layer 30 is provided on one side of the metallized ceramic heat dissipation substrate 20. The reflector layer 30 may be made of aluminum nitride, aluminum oxide which is similar to the material of the metallized ceramic heat dissipation substrate 20 or engineering plastics, such as PA9T or Teflon, Therefore, the refractory property of the reflector layer 30 is increased so as to avoid the embrittlement or cracking under high temperature in the long term.

As shown in FIG. 5C, an adhesive 40 is attached to the reflector layer 30 near the side of the metallized ceramic heat dissipation substrate 20. The adhesive 40 may be an acrylic material and is attached to the reflector layer 30 by coating, laminating, spraying, dip coating or immersion.

As shown in FIG. 5D, a through opening 31 is formed on the reflector layer 30 and the adhesive 40 by laser cutting, knife cutting or stamping molding.

As shown in FIG. 5E, the metallized ceramic heat dissipation substrate 20, and the adhesive 40 and the reflector layer 30 with the opening 31 are aligned and stacked, and the metallized ceramic heat dissipation substrate 20 and the reflector layer 30 are bonding through the adhesive 40 by a vacuum hot pressing process, to form the packaging structure with the opening 31.

In addition, the side of the reflector layer 30 near the opening 31 may be designed perpendicular to the metallized ceramic heat dissipation substrate 20. In another embodiment, the aperture of the opening 31 is tapered toward the surface of the metallized ceramic heat dissipation substrate 20. That is, the side of the reflector layer 30 near the opening 31 forms an inclined structure.

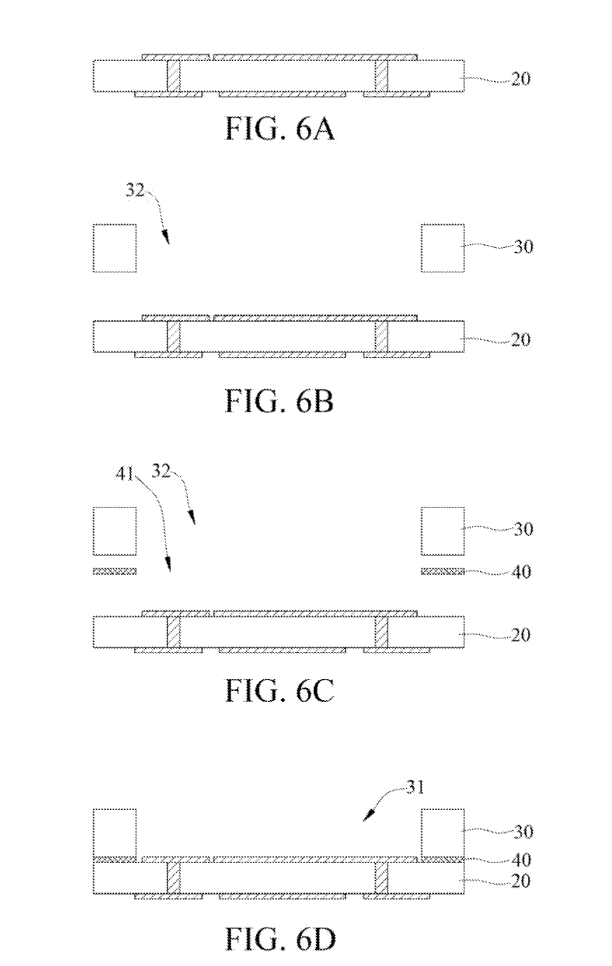

Referring to FIGS. 6A to 6D, cross-sectional views illustrating a method of fabricating a light emitting diode packaging structure according to another embodiment of the present invention are provided.

As shown in FIG. 6A, a metallized ceramic heat dissipation substrate 20 is provided, a circuit layer is disposed on the surface of the metallized ceramic heat dissipation substrate 20 and electrically connected to electronic components, and the metallized ceramic heat dissipation substrate 20 has a good thermal and electric separation capability.

As shown in FIG. 6B, a reflector layer 30 having a first opening 32 is provided. The reflector layer 30 is also made of aluminum nitride, aluminum oxide or engineering plastics, such as PA9T or Teflon. The refractory property of the reflector layer 30 may thus be improved. The first opening 32 may be formed by laser cutting, knife cutting, stamping molding, injection molding, hot pressing, etc.

As shown in FIG. 6C, an adhesive 40 having a second opening 41 is provided, the second opening 41 may be formed by laser cutting, knife cutting or stamping molding.

As shown in FIG. 6D, the first the opening 31 and the second the opening 41 are aligned for sequentially stacking the reflector layer 30, the adhesive 40 and the metallized ceramic heat dissipation substrate 20, and the metallized ceramic heat dissipation substrate 20 and the reflector layer 30 are joined by the adhesive 40 by a vacuum hot pressing process to form the packaging structure with the opening 31, in which the opening 31 is formed of the first the opening 32 and the second the opening 41.

The sidewall in the opening 31 of the reflector layer 30 may be perpendicular to the metallized ceramic heat dissipation substrate 20, in addition, in another embodiment, the aperture of the first the opening 32 may be slightly greater than or equal to that of the second opening 41. That is, the aperture of the opening 31 formed by the first opening 32 and the second opening 41 may be formed tapered from the side far from the metallized ceramic heat dissipation substrate 20 toward the surface of the metallized ceramic heat dissipation substrate 20, and the sidewall of the reflector layer 30 forms an inclined structure.

In summary, the light emitting diode packaging structure and method of fabricating the same according to the present invention mainly uses the ceramic or polymer engineering plastics materials to form the reflector layer, so as to prevent the reflector layer from embrittlement or cracking under high temperature in the long term. In addition, the present invention uses the adhesive to provide bonding strength between the metallized ceramic heat dissipation substrate and the reflector layer. Not only is the reliability therebetween strengthened, but also the entire structure is not required to be changed. That is, the subsequent LED packaging can he performed with the existing packaging machine, packaging costs does not increase and durable packaging structure is farther provided.

The above embodiments are illustrated to disclose the preferred implementation according to the present invention but not intended to limit the scope of the present invention, Accordingly, all modifications and variations completed by those with ordinary skill in the art should fall within the scope of present invention defined by the appended claims.

What is claimed is:

1. A light emitting diode package structure, comprising:
a metallized ceramic heat dissipation substrate;
a reflector layer formed on one side of the metallized ceramic heat dissipation substrate and having an opening for a surface of the metallized ceramic heat dissipation substrate to be exposed therefrom; and
an adhesive formed between the metallized ceramic heat dissipation substrate and the reflector layer for bonding the metallized ceramic heat dissipation substrate to the reflector layer.

2. The light emitting diode packaging structure of claim 1, wherein the reflector layer is made of aluminum nitride, aluminum oxide, PA9T or Teflon engineering plastics.

3. The light emitting diode packaging structure of claim 1 wherein the adhesive is acrylic adhesive.

4. The light emitting diode packaging structure of claim 1, further comprising:
a light emitting device disposed on the metallized ceramic heat dissipation substrate and exposed from the opening of the reflector layer; and
an encapsulant formed in the opening of the reflector layer for covering the light emitting device.

5. The light emitting diode packaging structure of claim 1, wherein the opening of the reflector layer has an aperture tapered toward the surface of the metallized ceramic heat dissipation substrate.

6. The light emitting diode packaging structure of claim 1, further comprising a circuit layer formed on the surface of the metallized ceramic heat dissipation substrate, wherein the adhesive covers the metallized ceramic heat dissipation substrate and the circuit layer.

7. A method of fabricating alight emitting diode package structure, comprising:
attaching an adhesive to a reflector layer;
forming an opening in the reflector layer attached to the adhesive; and
aligning the metallized ceramic heat dissipation substrate with the reflector layer, so as for the metallized ceramic heat dissipation substrate to be stacked on and coupled to the reflector layer via the adhesive by a vacuum hot pressing process.

8. The method of claim 7, wherein the opening of the reflector layer is formed by laser cutting, knife cutting or stamping molding.

9. The method of claim 7, wherein the adhesive is attached to the reflector layer by coating, laminating, spraying, dipping or immersing.

10. The method of claim 7, wherein the opening of the reflector layer has an aperture tapered toward a surface of the metallized ceramic heat dissipation substrate.

11. A method of fabricating a light emitting diode package structure, comprising:
providing a metallized ceramic heat dissipation substrate, a reflector layer having a first opening, and an adhesive having a second opening; and
aligning the first opening of the reflector layer with the second opening of the adhesive and stacking the metallized ceramic heat dissipation substrate on the adhesive which is adhered to the reflector layer, so as to couple the metallized ceramic heat dissipation substrate to the reflector layer via the adhesive by a vacuum hot pressing process.

12. The method of claim 11, wherein the first opening of the reflector layer is formed by laser cutting, knife cutting, stamping molding, injection molding or hot press molding.

13. The method of claim 11, wherein the second opening of the adhesive is formed by laser cutting, knife cutting or stamping molding.

14. The method of claim 11, wherein the first opening of the reflector layer has a first aperture greater in diameter than or equal in diameter to a second aperture of the second opening of the adhesive.
